(19) United States
(12) Patent Application Publication
(10) Pub. No.: US 2011/0234954 A1
(43) Pub. Date: Sep. 29, 2011

(54) METHOD OF FABRICATING A LIQUID CRYSTAL LENS, LIQUID CRYSTAL LENS AND LIQUID CRYSTAL ALIGNMENT SUBSTRATE FOR LIQUID CRYSTAL LENS PROVIDED BY THE SAME

(76) Inventors: Kuei-Chu HSU, Shulin City (TW); Tzu-Pin Kao, Tainan City (TW); Ching-Cherng Sun, Zhongli City (TW)

(21) Appl. No.: 12/797,221

(22) Filed: Jun. 9, 2010

(30) Foreign Application Priority Data
Mar. 23, 2010 (TW) 099108568

(51) Int. Cl. G02F 1/1337; G02F 1/13; G03F 7/20

(52) U.S. Cl. 349/123; 349/200; 430/20

(57) ABSTRACT

A method of fabricating an axially symmetric liquid crystal lens is disclosed, which comprises steps: (A) providing a first substrate; (B) forming a first conductive layer on the first substrate; (C) forming a first resist layer on the first conductive layer; (D) forming a first pattern with sub-micrometer period in the first resist layer by laser scanning; (E) developing the first resist layer to obtain a first patterned layer with sub-micrometer period; (F) providing a second substrate; and (G) forming a liquid crystal layer between the first patterned layer and the second substrate, wherein the first substrate, the first conductive layer, the first patterned layer, the liquid crystal layer, and the second substrate are sequentially arranged to form a layered structure. Also, an axially symmetric liquid crystal lens and liquid crystal alignment substrate for liquid crystal lens provided by the same are disclosed.

### BACKGROUND OF THE INVENTION

1. Field of the Invention

The present invention relates to a method of fabricating an axially symmetric liquid crystal lens, a liquid crystal lens provided by the same, and a liquid crystal alignment substrate for liquid crystal lens provided by the same and, more particularly, to a method of fabricating an axially symmetric liquid crystal lens by laser photolithography, a liquid crystal lens provided by the same, and a liquid crystal alignment substrate for liquid crystal lens provided by the same.

2. Description of Related Art

Focus tunable liquid crystal lenses (LC lenses) are generally used for focusing light in one dimension with electrically tunable focus. There are mainly two ways to realize electrically tunable focus lenses, one is by a complex design of the electrodes to achieve the desired alignment of LC molecules, and the other is by using a surface alignment method. As for a conventional LC lens, when there is no voltage applied, liquid crystal molecules in the LC lenses align in a single direction, in which the light transmitted through the LC lens is focused with the polarizing plates attached at the opposite sides of the LC lens. In an axially symmetric LC lens that is usually made with complex design of the electrodes and a pair of polarizers, but the attached polarizing plates at the opposite sides of the LC lens may reduce the light quantity, and therefore results in electricity consumption. Thus, there is a present need to provide a proper design to obtain convex lenses or concave lens by axially symmetric LC orientation without voltage being applied, in which the focus of the lenses can be tunable by applying voltage, and thus enable lenses to be widely used in many applications.

The traditional way of achieving the desired alignment of LC molecules by using a surface alignment method is the contact scheme of surface rubbing of the alignment layer. Usually, a rubbing cloth is used to rub the film and create grooves in the surface of the alignment layer for the LC molecules to align parallelly to the grooves. However, rubbing residues may be generated and static electricity may be generated during the rubbing process, and also it is difficult to achieve micro or nano scaled structures by such rubbing method.

Also, a mechanical micro scaled rubbing of the surface of the alignment film is proposed, which utilizes nano spheres as the grinding grains to produce microstructures in the alignment film. However, problems such as rubbing residues and static electricity due to the contact scheme still exist and the uniformity cannot be well controlled although axially symmetric LC orientation can be realized with such mechanical micro scaled rubbing method.

Alternatively, a non-contact photo-alignment method is also proposed, and alignment films similar to those obtained by rubbing can be obtained with high reproducibility by irradiating a dye-doped film on a large substrate area with polarized light. Such methods are for instance disclosed in WO 2009080271, U.S. Pat. No. 5,389,698, or U.S. Pat. No. 5,838,407. However, lengthy processing time is required in such photo-alignment method, which creates difficulty for large quantities to be manufactured. In a photo-alignment method, the alignment of the liquid crystals is achieved through photo-exposure, in which the light applied to the liquid crystals may be absorbed undesirably by the dyes contained in the photosensitive liquid crystals, and the merits of liquid crystal lenses may also be diminished by the dyes.

Therefore, it is desirable to provide an improved method for providing liquid crystal lenses to mitigate and/or obviate the aforementioned problems such as rubbing residues and static electricity in order to obtain liquid crystal lenses with high quality and enable liquid crystal lenses to be manufactured in large quantities, and reduce the using of the additives such as dyes in the photo sensitive materials for the producing of the liquid crystal alignment film.

### SUMMARY OF THE INVENTION

The present invention provides a method of fabricating an axially symmetric liquid crystal lens, which comprises steps: (A) providing a first substrate; (B) forming a first conductive layer on the first substrate; (C) forming a first resist layer on the first conductive layer; (D) forming a first pattern with sub-micrometer period in the first resist layer by laser scanning; (E) developing the first resist layer to obtain a first patterned layer with sub-micrometer period; (F) providing a second substrate; and (G) forming a liquid crystal layer between the first patterned layer and the second substrate, wherein the first substrate, the first conductive layer, the first patterned layer, the liquid crystal layer, and the second substrate are sequentially arranged to form a layered structure.

The method of fabricating an axially symmetric liquid crystal lens of the present invention utilizes laser direct writing techniques to pattern a photo-resist layer and form patterns such as a concentric circle, an axially symmetric polygon, or a spiral in the resist layer. Particularly, the present invention utilizes high intensity laser with nonlinear optics to form patterns with sub-micrometer period to provide a liquid crystal alignment substrate (i.e. an LC orientation directing substrate). That is, the top or the bottom surface of the pattern traces may be an undulating surface. According to the method of the present invention, the patterning (for example, a concentric circle, an axially symmetric polygon, or a spiral) of the resist layer can be realized by rotating the substrate while the laser writing is conducted, or can be realized by rotating the laser beam with the substrate fixed, both two methods are effective as long as a relative movement is performed between the laser beam and the substrate during the laser writing process.

According to the method of fabricating an axially symmetric liquid crystal lens of the present invention, the first pattern with sub-micrometer period is preferably an axially symmetric pattern such as a concentric circle, an axially symmetric polygon, or a spiral.

According to the method of fabricating an axially symmetric liquid crystal lens of the present invention, the first patterned layer may preferably enable liquid crystals to orient in a desired direction, which means the first patterned layer in the liquid crystal lens of the present invention may serve as a liquid crystal alignment layer in the present invention.

The method of fabricating an axially symmetric liquid crystal lens of the present invention utilizes laser direct writing techniques to pattern the photo-resist layer and therefore is able to avoid problems such as rubbing residues and static electricity, and also is able to improve the resolution of the formed sub-micrometer period pattern. Besides, compared with traditional non-contact photo-alignment method, the method of the present invention is advanced in short process time (short laser writing time), which is a benefit to large quantity manufacturing.

According to the method of fabricating an axially symmetric liquid crystal lens of the present invention, the laser used is preferably a titanium sapphire laser to achieve two-photon effect. Two-photon effect is a nonlinear optical phenomenon that occurs when the energy of the focused laser accumulates to a specific value (equivalent to the energy of two photons) and excites an electron from one state to an excited state and simultaneously accompany with the emitting of fluoresce light having around half of the wavelength of the light from a single-photon excitation (e.g. light having half of the wavelength of the original light of the titanium sapphire laser). According to the present invention, the resist layer may be made of organic monomers that can be polymerized by the exposure of the light having wavelength of ultra violet light to blue green light, which has half of the wavelength of the titanium sapphire laser (the wavelength of the titanium sapphire laser is about 800 nm). Consequently, the two-photon absorption light of high intensity is a nonlinear process thus is able to realize the pattern with sub-micrometer period in the photo-resist.

Furthermore, the period and the depth of the patterned resist (i.e. the micro-grating structure) may be adjustable depending on the writing speed and the power of the laser beam, and the direction of the sub-micrometer period structure (i.e. the direction of the grating structure) of the period resist pattern formed by the pulse laser can be modified by the polarizing direction of the laser beam. In order to obtain effective orientation of the liquid crystals, the period of the groove of the orientation/alignment layer (i.e. the patterned resist layer) should be a sub-micrometer period, in which a surface anchoring and an orientation behavior after voltage being applied can be adjusted by the period and the depth of the patterned resist. Therefore, the present invention utilizes two-photon effect to form grooves in various directions in the resist layer by controlling the polarizing direction of the laser writing, and form grooves with various periods and depths by controlling the laser writing speed. Hence, a complex axially symmetric pattern of the LC alignment film having desirable period and direction arrangement can be realized.

The method of fabricating an axially symmetric liquid crystal lens of the present invention may preferably further comprise steps (F1) to (F4) interposed between the step (F) and the step (G), wherein the step (F1) is forming a second conductive layer on the second substrate; the step (F2) is forming a second resist layer on the second conductive layer; the step (F3) is forming a second pattern with sub-micrometer period in the second resist layer by laser scanning; and the step (F4) is developing the second resist layer to obtain a second patterned layer with sub-micrometer period, wherein the liquid crystal layer in the step (G) locates between the first patterned layer and the second patterned layer, and the layered structure comprises the first substrate, the first conductive layer, the first patterned layer, the liquid crystal layer, the second patterned layer, the second conductive layer, and the second substrate arranged in series. The first and the second patterned layers locate on the first and the second substrates respectively, the patterns of the first and the second patterned layers share the same symmetry axis (or the spinning axle of a spiral), whereas the patterns of the first and the second patterned layer may be the same or different.

According to the method of fabricating an axially symmetric liquid crystal lens of the present invention, the first conductive layer and/or the second conductive layer is preferably made of ITO (indium tin oxide).

According to the method of fabricating an axially symmetric liquid crystal lens of the present invention, the first and/or the second pattern can be controlled by controlling the path of the laser writing, and the first and/or the second pattern may preferably be a concentric circle, an axially symmetric polygon, or a spiral, more preferably be an axially symmetric pattern.

According to the method of fabricating an axially symmetric liquid crystal lens of the present invention, an equivalent optical phase difference of the bottom or the top of the first and/or the second patterned layer may preferably increase or decrease from the center of the patterned layer to the edge of the patterned layer. In detail, the period and the depth of the sub-micrometer period structure is preferably increased or decreased in order to increase or decrease the surface anchoring of the liquid crystals, and which may result in the increasing or the decreasing of the equivalent optical phase difference to achieve the focusing function as lenses. In the present invention, the equivalent phase difference of the first and/or the second patterned layer is adjustable by controlling the writing speed of the laser used. When an equivalent optical phase difference of the bottom or the top of the first patterned layer increases from the center of the patterned layer to the edge of the patterned layer, the equivalent refractive index of the LCs from the center to the edge of the patterned layer may increase, which enables the liquid crystal lens of the present invention to serve as an axially symmetric LC convex lens. Alternatively, when the equivalent optical phase difference of the bottom or the top of the first patterned layer decreases from the center of the patterned layer to the edge of the patterned layer, an axially symmetric concave LC lens of the present invention is revealed.

According to the method of fabricating an axially symmetric liquid crystal lens of the present invention, the laser used in the step (D) for laser scanning is preferably a high-peak power pulse laser, and part of the first patterned layer in the step (E) and/or part of the second patterned layer in the step (F4) may preferably have an undulating surface with sub-micrometer period structure. While increasing the scanning speed of the laser, the sub-micrometer period structure (i.e. grating structure) of the patterned layer having undulating surface can be more significant whereas the interval of the period becomes short. When the scanning speed of the laser is lowered, the undulating surface of the patterned layer is not significant, and thus a flat surface at the top or the bottom of the patterned layer may be appeared. Therefore, by the adjusting of the laser scanning (writing) speed, the patterned layer wherein part of the surface is undulating surface and part of the surface is flat surface can be realized.

According to the present invention, the period and the depth of the patterned resist may be different depending on the writing speed and the power of the used pulse laser beam, and the direction of the gratings of the period pattern of the resist formed by the pulse laser can be modified by the polarizing direction of the laser beam. Accordingly, in the present invention, a laser writing process with adjustable polarizing direction and writing speed is used to therefore provide a complex axially symmetric pattern of the LC alignment film (i.e. the first and/or the second patterned layer) having desirable period and direction arrangement, and further to provide an axially symmetric liquid crystal lens.

According to the method of fabricating an axially symmetric liquid crystal lens of the present invention, the first resist layer and/or the second resist layer may preferably be made of positive photo-resist or a negative photo-resist.

According to the method of fabricating an axially symmetric liquid crystal lens of the present invention, the step (G) may preferably be: assembling the first and the second substrates and followed with injecting the liquid crystals into the space between the assembled first and the second substrates, and therefore a layered structure comprising the first conductive layer, the first patterned layer, the liquid crystal layer (and optionally the second patterned layer, the second conductive layer), and the second substrate in series is provided. Alternatively, the step (G) of the present invention may preferably be: forming a liquid crystal layer on the first patterned layer by one drop fill (ODF) process and followed by assembling the first and the second substrates, and therefore a layered structure comprising the first conductive layer, the first patterned layer, the liquid crystal layer (and optionally the second patterned layer, the second conductive layer), and the second substrate in series is provided.

The present invention also provides a liquid crystal lens, which comprises: a first substrate having a first conductive layer thereon, wherein a first patterned layer with sub-micrometer period locates on the first conductive layer, and the pattern of the first patterned layer is a concentric circle, an axially symmetric polygon, or a spiral; a second substrate; and a liquid crystal layer locating between the first substrate and the second substrate; wherein the first substrate, the first conductive layer, the first patterned layer having sub-micrometer period, the liquid crystal layer, and the second substrate are sequentially arranged to form a layered structure.

According to the liquid crystal lens of the present invention, the patterned layer may preferably enable liquid crystals to orient in a desired direction, which means the patterned layer in the liquid crystal lens of the present invention may serve as a liquid crystal alignment layer in the present invention. The patterned layer of the present invention may preferably be made by photolithography, and more preferably be made by laser photolithography in order to form sub-micrometer period in the patterned layer. The use of laser photolithography may contribute to avoid problems such as rubbing residues and static electricity, and also is able to improve the resolution of the formed sub-micrometer period pattern.

According to the liquid crystal lens of the present invention, the first pattern with sub-micrometer period is preferably an axially symmetric pattern.

Meanwhile, the liquid crystal lens of the present invention may preferably further comprise a second substrate having a second conductive layer thereon, wherein a second patterned layer with sub-micrometer period locates on the second conductive layer, and the pattern of the second patterned layer is a concentric circle, an axially symmetric polygon, or a spiral, the second patterned layer and the first patterned layer are arranged corresponding to each other to enable the liquid crystal layer to locate between the first patterned layer and the second patterned layer. According to the liquid crystal lens of the present invention, the pattern of the second patterned layer is preferably an axially symmetric pattern.

According to the liquid crystal lens of the present invention, the first and/or second is preferably made of ITO (indium tin oxide).

According to the liquid crystal lens of the present invention, an equivalent optical phase difference of the bottom or the top of the first and/or the second patterned layer may preferably increase or decrease from the center of the patterned layer to the edge of the patterned layer. In the present invention, the equivalent phase difference of the first and/or the second patterned layer is adjustable by controlling the writing speed of the laser used. In detail, the period and the depth of the sub-micrometer period structure is carefully modified in order to adjust the surface anchoring (i.e. the anchoring force) of the liquid crystals and to achieve the desired the equivalent optical phase difference (i.e. the focusing function as lenses). In the present invention, the equivalent phase difference of the first and/or the second patterned layer is adjustable by controlling the writing speed of the laser used in the laser photolithography. When an equivalent phase difference of the bottom or the top of the first patterned layer increases from the center of the patterned layer to the edge of the patterned layer, the equivalent refractive index of the LCs from the center to the edge of the patterned layer may increase, which enables the liquid crystal lens of the present invention to serve as an axially symmetric LC convex lens. Alternatively, when the equivalent optical phase difference of the bottom or the top of the first patterned layer decreases from the center of the patterned layer to the edge of the patterned layer, an axially symmetric concave LC lens of the present invention is revealed.

According to the liquid crystal lens of the present invention, when a pulse laser is used in the laser photolithography, a nonlinear optical phenomenon may occur to enhance the polymerization of the resist, and thus a patterned layer with sub-micrometer period can be formed. Furthermore, the period and the depth of the patterned resist may be adjustable depending on the writing speed and the power of the laser beam, and the direction of the sub-micrometer period structure (i.e. the direction of the grating structure) of the period resist pattern formed by the pulse laser can be modified by the polarizing direction of the laser beam, which can not be achieved by the prior arts.

Moreover, compared with the liquid crystal lens made by a conventional photo-alignment method, the liquid crystal lens of the present invention is able to perform a better resolution of the formed sub-micrometer period pattern (i.e. the grating structure).

The present invention also provides a liquid crystal alignment substrate for liquid crystal lens, which comprises: a substrate; a conductive layer locating on the substrate; and a patterned layer having sub-micrometer period, wherein the pattern of the patterned layer is a concentric circle, an axially symmetric polygon, or a spiral.

According to the liquid crystal alignment substrate for liquid crystal lens of the present invention, the pattern of the patterned layer having sub-micrometer period is preferably an axially symmetric pattern.

The liquid crystal alignment substrate for liquid crystal lens of the present invention is an excellent liquid crystal alignment substrate because the patterned layer having sub-micrometer period enables liquid crystals to orient in a desired direction, which means the patterned layer of the LC alignment substrate serves as an alignment layer in the present invention. Meanwhile, in the present invention, the pattern of the patterned layer with sub-micrometer period is preferably an axially symmetric pattern for being used to provide an axially symmetric liquid crystal lens.

According to the liquid crystal alignment substrate for liquid crystal lens of the present invention, an equivalent optical phase difference of the bottom or the top of the patterned layer may preferably increase or decrease from the center of the patterned layer to the edge of the patterned layer.

According to the liquid crystal alignment substrate for liquid crystal lens of the present invention, preferably part of the patterned layer has an undulating surface.

The patterned layer of the present invention may preferably be made by photolithography, and more preferably be made by laser photolithography in order to form a sub-micrometer period in the patterned layer.

Other objects, advantages, and novel features of the invention will become more apparent from the following detailed description when taken in conjunction with the accompanying drawings.

### BRIEF DESCRIPTION OF THE DRAWINGS

FIGS. 1A to 1F are the process flow chart showing the method of fabricating a liquid crystal lens of the example 1 of the present invention;

FIGS. 2A to 2C are the profile section view along the lines A-A′, B-B′, and C-C′ in the FIG. 1E;

FIGS. 3 to 5 are the schematic views showing the patterns of the pattern layer of the present invention;

FIGS. 6A to 6D are the process flow chart showing the method of fabricating a liquid crystal alignment substrate for liquid crystal lens of the example 3 of the present invention; and

FIG. 7 is the profile section view of the liquid crystal lens of the example 4 of the present invention.

### DETAILED DESCRIPTION OF THE PREFERRED EMBODIMENT

### Example 1

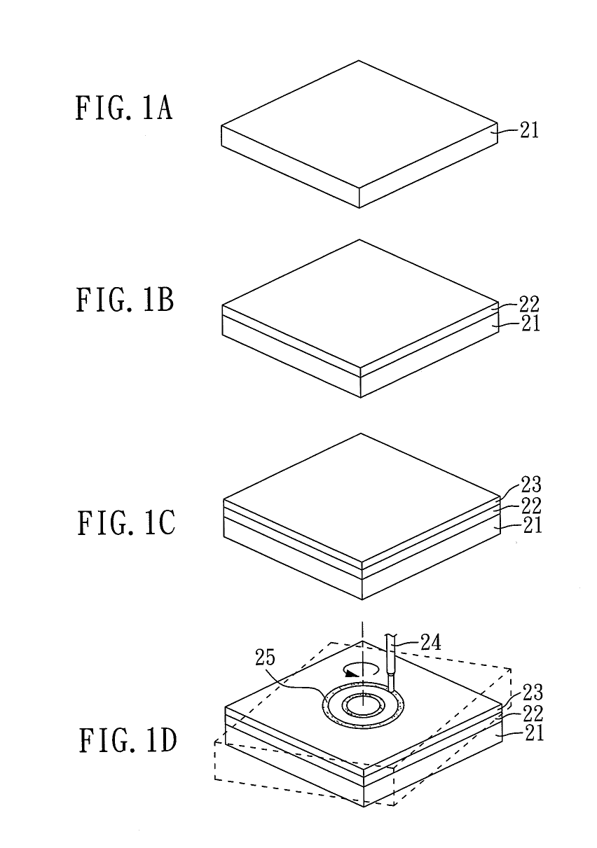

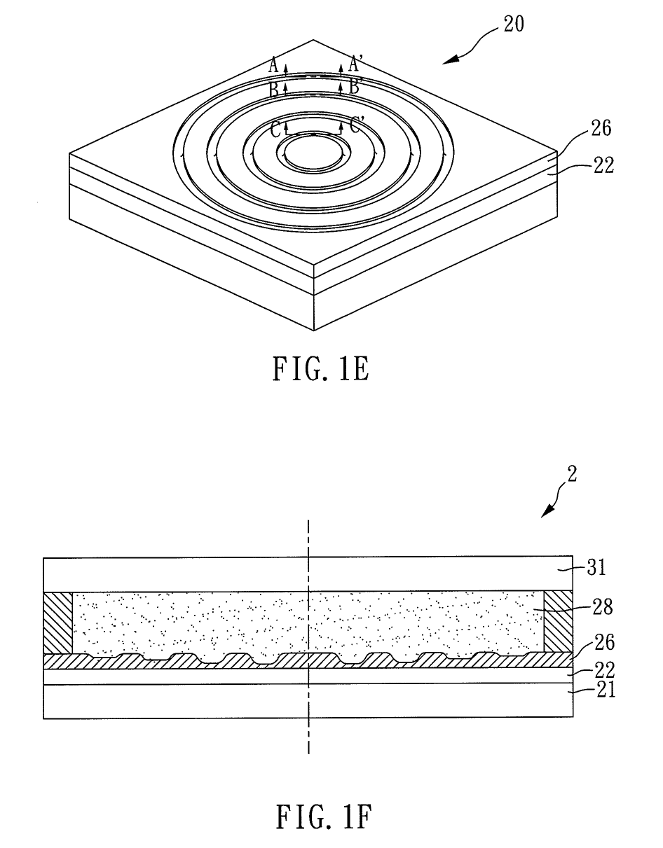

Reference with FIGS. 1A to 1F, in which the process flow chart of fabricating a liquid crystal lens of the example 1 of the present invention is shown. First, (A) a first substrate 21 is provided as shown in FIG. 1A and then (B) a first conductive layer 22 (an ITO layer) is formed on the first substrate 21 as shown in FIG. 1B. Then, (C) a first resist layer 23 is formed on the first conductive layer 22 as shown in FIG. 1C, (D) a first pattern 25 with a sub-micrometer period is formed in the first resist layer 23 by using a pulse laser 24 to scan as shown in FIG. 1D. Herein, the first substrate 21 is rotated during the laser writing performed with the pulse laser 24. Subsequently, (E) the first resist layer 23 is developed to obtain a first patterned layer 26 with sub-micrometer period, and thus a first liquid crystal alignment substrate 20 is achieved as shown in FIG. 1E.

After that, (F) a second substrate 31 is provided and (G) a liquid crystal layer 28 is formed between the first patterned layer 26 and the second substrate 31, in which the first substrate 21, the first conductive layer 22, the first patterned layer 26, the liquid crystal layer 28, and the second substrate 31 are sequentially arranged to form a layered structure i.e. the liquid crystal lens 2 of the present example, as shown in FIG. 1F.

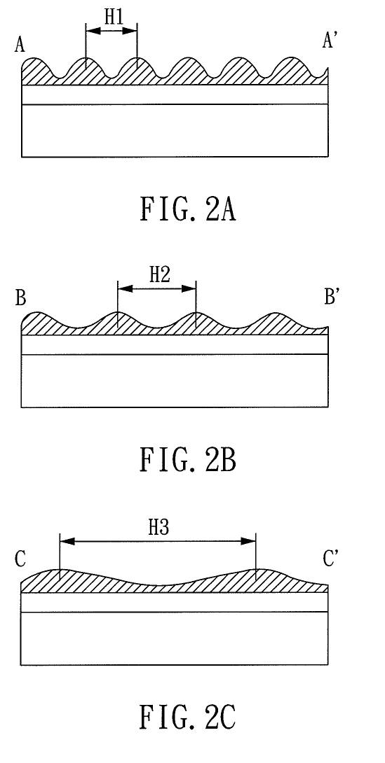

Reference with FIGS. 2A to 2C, in which profile section views along the lines A-A′, B-B′, and C-C′ in FIG. 1E are shown. According to the present example, the pattern of the first patterned layer 26 is a concentric circle, the equivalent optical phase difference of the bottom of the first patterned layer 26 increases from the center of the first patterned layer 26 to the edge of the first patterned layer 26. In detail, as shown in FIG. 2C, the sub-micrometer period interval H1 locating near the center of the first patterned layer 26 is shorter than the sub-micrometer period interval H2 (i.e. the length H1<H2), and the sub-micrometer period interval H3 locating near the edge of the first patterned layer 26 is the longest. That is, the sub-micrometer period at the position of line A-A′ is denser than the sub-micrometer period at the position of line B-B′, and the sub-micrometer period at the position of line C-C′ is the sparsest, because the laser writing speed is lowered when applied at the position of line C-C′ (near the central position of the patterned layer) and the laser writing speed is raised when applied at the position of line A-A′ (near the edge position of the patterned layer). Therefore, an undulating surface with a sub-micrometer period structure (i.e. the grating structure) of the patterned layer can be provided. Meanwhile, in the present invention, the direction of the gratings of the period pattern of the resist formed by the pulse laser can be modified by the polarizing direction of the laser beam.

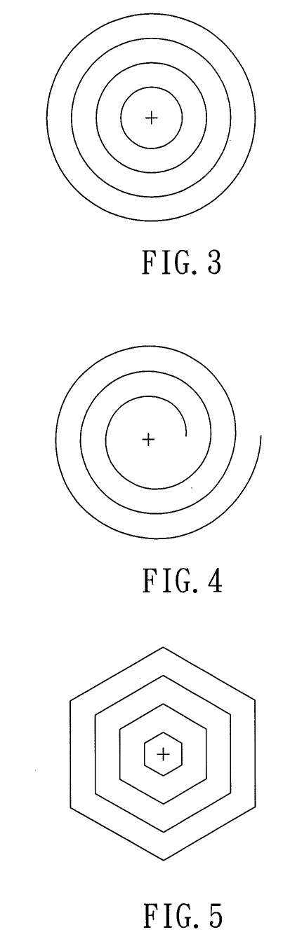

Herein, the first pattern 25 with the sub-micrometer period in the step (D) is a concentric circle as shown in FIG. 3, but is not limited thereto, the first pattern 25 may also be a spiral as shown in FIG. 4 or an axially symmetric polygon such as concentric hexagon as shown in FIG. 5.

### Example 2

Reference with FIG. 1F, the liquid crystal lens 2 of the present example is shown, which comprises: a first substrate 21 having a first conductive layer 22 thereon, wherein a first patterned layer 26 with a sub-micrometer period locates on the first conductive layer 22, and the pattern of the first patterned layer 26 is a concentric circle; a second substrate 31; and a liquid crystal layer 28 locating between the first substrate 21 and the second substrate 31; wherein the first substrate 21, the first conductive layer 22, the first patterned layer 26 having a sub-micrometer period, the liquid crystal layer 28, and the second substrate 31 are sequentially arranged to form a layered structure i.e. the liquid crystal lens 2 of the present example.

### Example 3

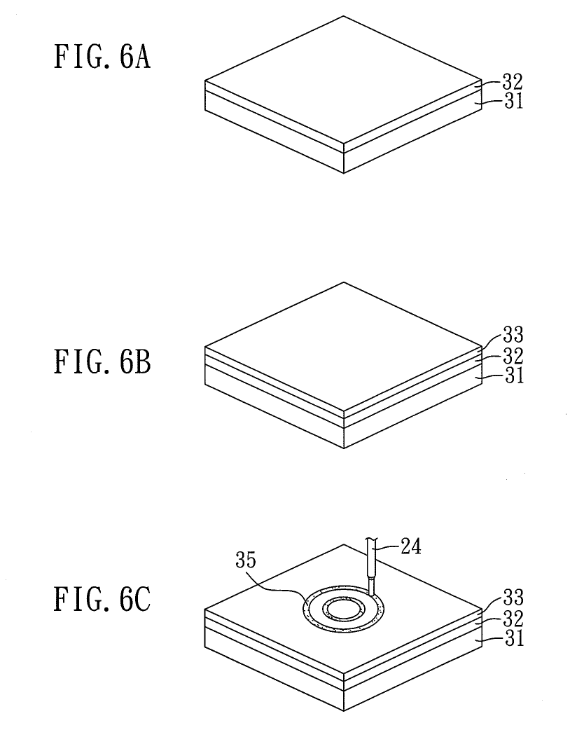

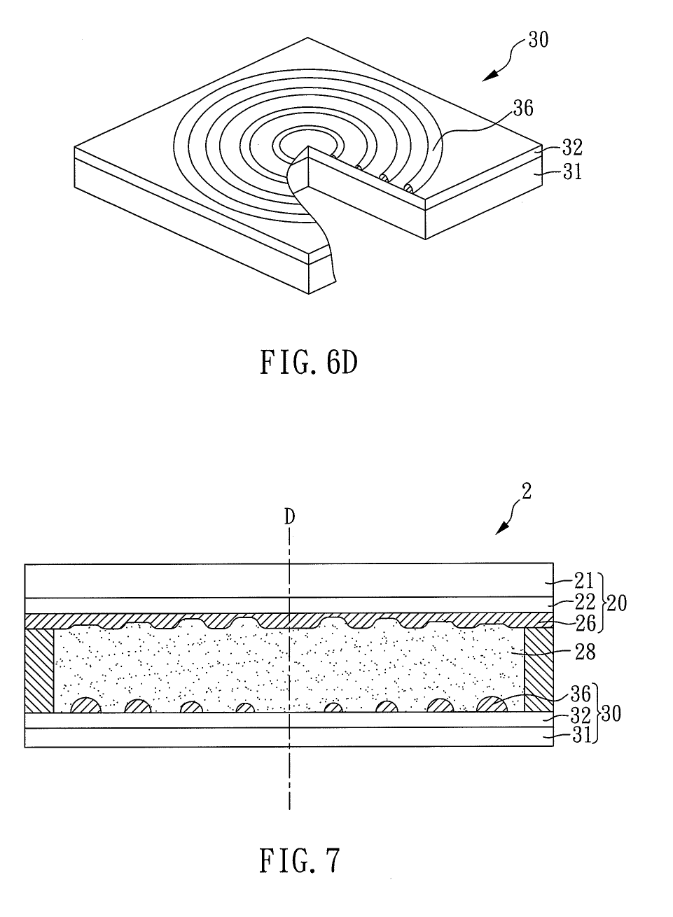

First, a first liquid crystal alignment substrate 20 is prepared in the same method (steps (A) to (E)) as described in the example 1, in which the first liquid crystal alignment substrate 20 has a first conductive layer 22 and a first patterned layer 26 having sub-micrometer period. Then, reference with FIGS. 6A to 6D, a second liquid crystal alignment substrate 30 having a second patterned layer 36 with sub-micrometer period is formed by steps (F1) to (F4), in which the step (F1) is forming a second conductive layer 32 on the second substrate 31 as shown in FIG. 6A; the step (F2) is forming a second resist layer 33 on the second conductive layer 32 as shown in FIG. 6B; the step (F3) is forming a second pattern 35 with sub-micrometer period in the second resist layer 33 by a pulse laser beam 24 as shown in FIG. 6C; and the step (F4) is developing the second resist layer 33 to obtain a second patterned layer 36 with sub-micrometer period as shown in FIG. 6D. Herein, the second resist layer 33 is made of negative photo-resist instead of positive photo-resist. The provided second liquid crystal alignment substrate 30 is shown in FIG. 6D.

Then, the first liquid crystal alignment substrate 20 and the second liquid crystal alignment substrate 30 are assembled, and liquid crystal is injected into the space between the assembled first and the second liquid crystal alignment substrates 20,30 to form a liquid crystal layer 28. Thus a liquid crystal lens 2 of the present example is obtained, wherein the liquid crystal lens 2 comprises: a first substrate 21, a first conductive layer 22, a first patterned layer 26, a liquid crystal layer 28, a second patterned layer 36, a second conductive layer 32, and a second substrate 31 in series as shown in FIG. 7.

In the present example, the second patterned layer 36 is made of negative photo-resist, and the equivalent phase difference of the top of the second patterned layer 36 increases from the center of the second patterned layer 36 to the edge of the second patterned layer 36. The patterns of the first and the second patterned layers 26,36 share the same symmetry axis D as shown in FIG. 7, in order to obtain a liquid crystal lens 2 having excellent optical characteristics.

### Example 4

Reference with FIG. 7, a liquid crystal lens 2 of the present example is shown, which comprises: a first substrate 21 having a first conductive layer 22 thereon, wherein a first patterned layer 26 with sub-micrometer period locates on the first conductive layer 22, and the pattern of the first patterned layer 26 is a concentric circle; a second substrate 31 having a second conductive layer 32 thereon, wherein a second patterned layer 36 with sub-micrometer period locates on the second conductive layer 32 and the pattern of the second patterned layer 36 is a concentric circle, the second patterned layer 36 and the first patterned layer 26 are arranged corresponding to each other and the patterns of the first and the second patterned layers 26,36 share the same symmetry axis D; and a liquid crystal layer 28 locating between the first substrate 21 and the second substrate 31; wherein the first substrate 21, the first conductive layer 22, the first patterned layer 26 having sub-micrometer period, the liquid crystal layer 28, the second patterned layer 36, the second conductive layer 32, and the second substrate 31 are sequentially arranged to form a layered structure i.e. the liquid crystal lens 2 of the present example.

As shown in FIG. 7, in the present example, the equivalent phase difference of the bottom of the first patterned layer 26 increases from the center of the first patterned layer 26 to the edge of the first patterned layer 26, and the equivalent phase difference of the top of the second patterned layer 36 increases from the center of the first patterned layer 36 to the edge of the first patterned layer 36.

As mentioned above, the present invention utilizes laser direct writing techniques to pattern a photo-resist layer and form patterns such as a concentric circle, an axially symmetric polygon, or a spiral in the resist layer. Particularly, the present invention utilizes high peak intensity laser pulse to induce nonlinear effect to form patterns with sub-micrometer period to provide alignment layers on the substrate. According to the method of the present invention, the patterning of the resist layer can be realized by rotating the substrate while the laser writing is conducted, or can be realized by rotating the laser beam with the substrate fixed, both two methods are effective as long as a relative movement is performed between the laser beam and the substrate during the laser writing process.

According to the method of fabricating an axially symmetric liquid crystal lens of the present invention, the patterned layer enables liquid crystals to orient in a desired direction, which means the patterned layer in the liquid crystal lens of the present invention may serve as an alignment layer in the present invention.

The method of fabricating an axially symmetric liquid crystal lens of the present invention utilizes laser direct writing techniques to pattern the photo-resist layer and therefore is able to avoid problems such as rubbing residues and static electricity, and also is able to improve the resolution of the formed sub-micrometer period pattern. Besides, compared with traditional non-contact photo-alignment method, the method of the present invention is advanced in short process time (short laser writing time), which is a benefit to large quantity manufacturing.

According to the liquid crystal lens of the present invention, when a pulse laser is used in the laser photolithography, nonlinear optical phenomenon may occur to enhance the polymerization of the resist, and thus patterned layer with sub-micrometer period can be formed. Furthermore, the period (dense or sparse) and the depth of the patterned resist can be adjusted depending on the writing speed and the power of the laser beam, and part of the patterned layer may have an undulating surface or a flat surface. In the present invention, the direction of the sub-micrometer period structure (i.e. the direction of the grating structure) of the period resist pattern formed by the pulse laser can be modified by the polarizing direction of the laser beam. Therefore, it is possible to provide a complex axially symmetric pattern of the LC alignment film (i.e. the first and/or the second patterned layer) having desirable period and direction arrangement, and further to provide an axially symmetric liquid crystal lens, which can not be achieved by the prior arts.

Although the present invention has been explained in relation to its preferred embodiment, it is to be understood that many other possible modifications and variations can be made without departing from the scope of the invention as hereinafter claimed.

What is claimed is:

1. A method of fabricating an axially symmetric liquid crystal lens, which comprises steps:
(A) providing a first substrate;
(B) forming a first conductive layer on the first substrate;
(C) forming a first resist layer on the first conductive layer;
(D) forming a first pattern with sub-micrometer period in the first resist layer by laser scanning;
(E) developing the first resist layer to obtain a first patterned layer with sub-micrometer period;
(F) providing a second substrate; and
(G) forming a liquid crystal layer between the first patterned layer and the second substrate,
wherein the first substrate, the first conductive layer, the first patterned layer, the liquid crystal layer, and the second substrate are sequentially arranged to form a layered structure.

2. The method of fabricating an axially symmetric liquid crystal lens as claimed in claim 1, wherein the first pattern with sub-micrometer period is an axially symmetric pattern.

3. The method of fabricating an axially symmetric liquid crystal lens as claimed in claim 1, further comprises steps (F1) to (F4) interposed between the step (F) and the step (G), wherein the step (F1) is forming a second conductive layer on the second substrate; the step (F2) is forming a second resist layer on the second conductive layer; the step (F3) is forming a second pattern with sub-micrometer period in the second resist layer by laser scanning; and the step (F4) is developing the second resist layer to obtain a second patterned layer with sub-micrometer period, wherein the liquid crystal layer in the step (G) locates between the first patterned layer and the second patterned layer, and the layered structure comprises the first substrate, the first conductive layer, the first patterned layer, the liquid crystal layer, the second patterned layer, the second conductive layer, and the second substrate arranged in series.

4. The method of fabricating an axially symmetric liquid crystal lens as claimed in claim 1, wherein a pattern of the first pattern with sub-micrometer period is a concentric circle, an axially symmetric polygon, or a spiral.

5. The method of fabricating an axially symmetric liquid crystal lens as claimed in claim 2, wherein a pattern of the second pattern with sub-micrometer period is a concentric circle, an axially symmetric polygon, or a spiral.

6. The method of fabricating an axially symmetric liquid crystal lens as claimed in claim 1, wherein an equivalent optical phase difference of the bottom or the top of the first patterned layer increases from the center of the first patterned layer to the edge of the first patterned layer.

7. The method of fabricating an axially symmetric liquid crystal lens as claimed in claim 1, wherein an equivalent phase difference of the bottom or the top of the first patterned layer decreases from the center of the first patterned layer to the edge of the first patterned layer.

8. The method of fabricating an axially symmetric liquid crystal lens as claimed in claim 1, wherein the laser used in the step (D) for laser scanning is a pulse laser.

9. The method of fabricating an axially symmetric liquid crystal lens as claimed in claim 1, wherein the first resist layer is made of positive photo-resist or a negative photo-resist.

10. A liquid crystal lens, which comprises:
a first substrate having a first conductive layer thereon, wherein a first patterned layer with sub-micrometer period locates on the first conductive layer, and the pattern of the first patterned layer is a concentric circle, an axially symmetric polygon, or a spiral;
a second substrate; and
a liquid crystal layer locating between the first substrate and the second substrate;
wherein the first substrate, the first conductive layer, the first patterned layer having sub-micrometer period, the liquid crystal layer, and the second substrate are sequentially arranged to form a layered structure.

11. The liquid crystal lens as claimed in claim 10, wherein the pattern of the first patterned layer is an axially symmetric pattern.

12. The liquid crystal lens as claimed in claim 10, further comprises a second substrate having a second conductive layer thereon, wherein a second patterned layer with sub-micrometer period locates on the second conductive layer, and the pattern of the second patterned layer is a concentric circle, an axially symmetric polygon, or a spiral, the second patterned layer and the first patterned layer are arranged corresponding to each other to enable the liquid crystal layer to locate between the first patterned layer and the second patterned layer.

13. The liquid crystal lens as claimed in claim 10, wherein an equivalent phase difference of the bottom or the top of the first patterned layer increases from the center of the first patterned layer to the edge of the first patterned layer.

14. The liquid crystal lens as claimed in claim 10, wherein an equivalent phase difference of the bottom or the top of the first patterned layer decreases from the center of the first patterned layer to the edge of the first patterned layer.

15. The liquid crystal lens as claimed in claim 10, wherein part of the first patterned layer has an undulating surface.

16. The liquid crystal lens as claimed in claim 10, wherein part of the second patterned layer has an undulating surface.

17. The liquid crystal lens as claimed in claim 10, wherein the first patterned layer with sub-micrometer period is made by laser photolithography.

18. A liquid crystal alignment substrate for liquid crystal lens, which comprises:
a substrate;
a conductive layer locating on the substrate; and
a patterned layer having sub-micrometer period, wherein the pattern of the patterned layer is a concentric circle, an axially symmetric polygon, or a spiral.

19. The liquid crystal alignment substrate for liquid crystal lens as claimed in claim 18, wherein a pattern of the patterned layer is an axially symmetric pattern.

20. The liquid crystal alignment substrate for liquid crystal lens as claimed in claim 18, wherein an equivalent phase difference of the bottom or the top of the patterned layer increases from the center of the patterned layer to the edge of the patterned layer.

21. The liquid crystal alignment substrate for liquid crystal lens as claimed in claim 18, wherein an equivalent phase difference of the bottom or the top of the patterned layer decreases from the center of the patterned layer to the edge of the patterned layer.

22. The liquid crystal alignment substrate for liquid crystal lens as claimed in claim 18, wherein part of the patterned layer has an undulating surface.

23. The liquid crystal alignment substrate for liquid crystal lens as claimed in claim 18, wherein the patterned layer with sub-micrometer period is made by laser photolithography.
